(19) United States
(12) Patent Application Publication
(10) Pub. No.: US 2026/0198163 A1
(43) Pub. Date: Jul. 9, 2026

(54) WINDOW, METHOD OF MANUFACTURING THE SAME, AND ELECTRONIC APPARATUS INCLUDING THE WINDOW

(71) Applicant: Samsung Display Co., Ltd., Yongin-si (KR)

(72) Inventors: Hyunseok OH, Yongin-si (KR); SEUNG-WON KUK, Yongin-si (KR); HYUNKYUNG YUN, Yongin-si (KR); KANG-WOO LEE, Yongin-si (KR); JOOHYEON LEE, Yongin-si (KR)

(21) Appl. No.: 19/317,918

(22) Filed: Sep. 3, 2025

(30) Foreign Application Priority Data
Jan. 3, 2025 (KR) 10-2025-0001102

(51) Int. Cl. H10H 29/855; G06F 1/16; H10H 29/01; H10K 59/80; H10K 77/10

(52) U.S. Cl. CPC H10H 29/8552; G06F 1/1652; H10H 29/0363; H10K 59/8792; H10K 77/111

(57) ABSTRACT

A manufacturing method of a window includes placing a substrate in a guide film accommodating the substrate and provided with an opening, which is defined through a guide film to overlap a portion of the substrate in a plan view, providing a first solution, which contains a light blocking particle and a polymer resin, to an edge portion of an inner space of the guide film, where the inner space is divided into a center portion overlapping the opening in the plan view and the edge portion, which is outside the center portion, providing a second solution containing the polymer resin to the center portion, placing a magnet to overlap the edge portion in the plan view to allow the light blocking particle to move by the magnet, and curing the light blocking particle and the polymer resin using ultraviolet light to form the black matrix and the coating layer.

This application claims priority to Korean Patent Application No. 10-2025-0001102, filed on Jan. 3, 2025, and all the benefits accruing therefrom under 35 U.S.C. § 119, the content of which in its entirety is herein incorporated by reference.

### BACKGROUND

### 1. Field

The present disclosure relates to a foldable window, a method of manufacturing the window, and an electronic apparatus including the window. More particularly, the present disclosure relates to a method of manufacturing a window, which is capable of forming a black matrix with a single curing process, the window, and an electronic apparatus including the window.

### 2. Description of Related Art

Various types of electronic apparatuses are being used to provide image information, and recently, electronic apparatuses including a flexible display panel that is foldable or bendable are being developed. Unlike rigid electronic apparatuses, flexible electronic apparatuses are able to be folded, rolled, or bent into various shapes, making them easily portable regardless of the size of its screen displaying images.

The flexible electronic apparatuses require a window that protects the display panel without causing disruption to the folding or bending operation.

### SUMMARY

The present disclosure provides a method of manufacturing a window designed to prevent swelling and void formation after a black matrix is formed and a resin is coated during a printing process.

The present disclosure provides an electronic apparatus including a window designed to prevent swelling and void formation after a black matrix is formed and a resin is coated during a printing process.

Embodiments of the invention provide a method of manufacturing a window including a folding area, a first non-folding area adjacent to one side of the folding area, and a second non-folding area adjacent to the other side of the folding area and including a substrate, a coating layer disposed under the substrate, and a black matrix. The method includes placing the substrate in a guide film accommodating the substrate and provided with an opening, which is defined through the guide film to overlap a portion of the substrate in a plan view, providing a first solution, which contains a light blocking particle and a polymer resin, to an edge portion of an inner space of the guide film, where the inner space is divided into a center portion overlapping the opening in the plan view and the edge portion, which is outside the center portion, providing a second solution containing the polymer resin to the center portion, placing a magnet to overlap the edge portion in the plan view to allow the light blocking particle to move by the magnet, and curing the light blocking particle and the polymer resin using an ultraviolet light to form the black matrix and the coating layer.

The coating layer may include a first surface adjacent to the substrate and a second surface opposite to the first surface, and a portion of the first surface has a convex shape toward the substrate.

The substrate may include a first portion overlapping the first non-folding area, a second portion overlapping the second non-folding area, and a third portion overlapping the folding area and having a thickness smaller than each of thicknesses of the first and second portions, and the third portion has a curvature.

The method may further include partially cutting the edge portion using a laser beam, turning over the substrate and the coating layer, and removing the guide film.

The light blocking particle may have ferromagnetism and a light blocking property.

The light blocking particle may be formed by coating a first material having a light blocking property on a first portion having ferromagnetism.

The light blocking particle may include Fe, Co, Ni, Mn, Fe₂O₃, or Fe₃O₄.

The guide film may include a transparent material that transmits the ultraviolet light.

Placing the magnet to overlap the edge portion may include placing the magnet under the guide film to allow the light blocking particle to be in contact with the substrate.

Placing the magnet to overlap the edge portion may include placing the magnet on the guide film to allow the light blocking particle to be separated from the substrate and to be in contact with the guide film.

Placing the magnet to overlap the edge portion may include placing the magnet on a side surface of the guide film to allow the light blocking particle to be arranged in a side surface of the substrate.

Curing the light blocking particle and the polymer resin may include simultaneously forming the black matrix and the coating layer.

Embodiments of the invention provide an electronic apparatus including a window including a folding area, a first non-folding area adjacent to one side of the folding area, and a second non-folding area adjacent to the other side of the folding area, a display module disposed under the window, and a housing accommodating the display module. The window includes a substrate, a coating layer disposed under the substrate, and a black matrix. The substrate has a concave shape in the folding area, the coating layer has a convex shape in the folding area, the substrate is spaced apart from the display module, the coating layer is disposed between the substrate and the display module, and the black matrix has ferromagnetism and a light blocking property.

The electronic apparatus may further include an adhesive layer disposed under the window, and the display module is disposed under the adhesive layer.

The black matrix may include a plurality of light blocking particles.

Each of the light blocking particles may include a first portion having the ferromagnetism and a first material coated on the first portion and having the light blocking property.

Each of the light blocking particles may include Fe, Co, Ni, Mn, Fe₂O₃, or Fe₃O₄.

The black matrix may be disposed between the substrate and the coating layer.

The black matrix may be disposed between the coating layer and the adhesive layer.

The black matrix is disposed adjacent to a side surface of the substrate and a side surface of the coating layer, and the black matrix does not overlap the display module in a plan view.

According to the method of manufacturing the window, the black matrix and the coating layer are simultaneously formed by curing the light blocking particles and the polymer resin using ultraviolet light. Thus, the manufacturing processes used to form the window are effectively simplified.

According to the electronic device including the window, since the light blocking particles in the edge portion move by the magnet, it is possible to effectively prevent swelling and void formation from occurring after the black matrix is formed and the resin is coated.

### BRIEF DESCRIPTION OF THE DRAWINGS

FIG. 1 is a block diagram showing an electronic apparatus according to an embodiment of the present disclosure;

FIG. 2 is a view showing electronic apparatuses according to embodiments of the present disclosure;

FIG. 3A is a perspective view showing an electronic apparatus according to an embodiment of the present disclosure;

FIG. 3B is a perspective view showing an electronic apparatus according to an embodiment of the present disclosure;

FIG. 3C is a plan view showing an electronic apparatus according to an embodiment of the present disclosure;

FIG. 3D is a perspective view showing an electronic apparatus according to an embodiment of the present disclosure;

FIG. 4A is a perspective view showing an electronic apparatus according to an embodiment of the present disclosure;

FIG. 4B is a perspective view showing an electronic apparatus according to an embodiment of the present disclosure;

FIG. 4C is a perspective view showing an electronic apparatus according to an embodiment of the present disclosure;

FIG. 5 is an exploded perspective view showing an electronic apparatus according to an embodiment of the present disclosure;

FIG. 6A is a cross-sectional view taken along line I-I′ of FIG. 3;

FIG. 6B is a cross-sectional view showing a portion of an electronic apparatus according to an embodiment of the present disclosure;

FIG. 7 is a flowchart showing a method of manufacturing a window according to an embodiment of the present disclosure;

FIG. 8A is a view showing a process of manufacturing a window according to an embodiment of the present disclosure;

FIG. 8B is a view showing a process of manufacturing a window according to an embodiment of the present disclosure;

FIG. 8C is a view showing a process of manufacturing a window according to an embodiment of the present disclosure;

FIG. 8D is a view showing a process of manufacturing a window according to an embodiment of the present disclosure;

FIG. 8E is a view showing a process of manufacturing a window according to an embodiment of the present disclosure;

FIG. 8F is a view showing a process of manufacturing a window according to an embodiment of the present disclosure;

FIG. 8G is a view showing a process of manufacturing a window according to an embodiment of the present disclosure;

FIG. 8H is a view showing a process of manufacturing a window according to an embodiment of the present disclosure;

FIG. 9A is a view showing a process of manufacturing a window according to an embodiment of the present disclosure;

FIG. 9B is a view showing a process of manufacturing a window according to an embodiment of the present disclosure;

FIG. 10 is a cross-sectional view showing a portion of an electronic apparatus according to an embodiment of the present disclosure;

FIG. 11A is a view showing a process of manufacturing a window according to an embodiment of the present disclosure;

FIG. 11B is a view showing a process of manufacturing a window according to an embodiment of the present disclosure; and

FIG. 12 is a cross-sectional view showing a portion of an electronic apparatus according to an embodiment of the present disclosure.

### DETAILED DESCRIPTION

In the present disclosure, it will be understood that when an element (or area, layer, or portion) is referred to as being “on”, “connected to” or “coupled to” another element or layer, it can be directly on, connected or coupled to the other element or layer or intervening elements or layers may be present.

Like numerals refer to like elements throughout. In the drawings, the thickness, ratio, and dimension of components are exaggerated for effective description of the technical content. As used herein, the term “and/or” may include any and all combinations of one or more of the associated listed items.

It will be understood that, although the terms “first”, “second”, etc. may be used herein to describe various elements, these elements should not be limited by these terms. These terms are only used to distinguish one element from another element. Thus, a first element discussed below could be termed a second element without departing from the teachings of the present disclosure. As an example, without departing from the scope of the present disclosure, a first component, a first part, a first region, a first layer, and a first portion are referred to as a second component, a second part, a second region, a second layer, and a second portion, respectively, and vice versa. As used herein, the singular forms, “a”, “an” and “the” are intended to include the plural forms as well, unless the context clearly indicates otherwise.

Spatially relative terms, such as “below”, “lower”, “above”, “upper” and the like, may be used herein for ease of description to describe one element or feature's relationship to another elements or features as shown in the figures.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, embodiments of the present disclosure will be described with reference to accompanying drawings.

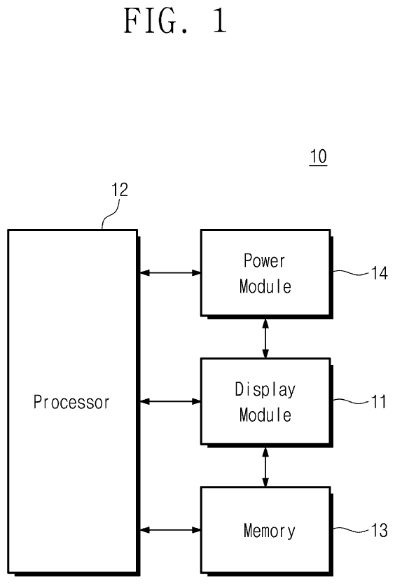

FIG. 1 is a block diagram of an electronic apparatus according to an embodiment of the present disclosure. Referring to FIG. 1, the electronic apparatus 10 may include a display module 11, a processor 12, a memory 13, and a power module 14.

The processor 12 may include at least one of a central processing unit (CPU), an application processor (AP), a graphics processing unit (GPU), a communication processor (CP), an image signal processor (ISP), and a controller.

The memory 13 may store data information required for the operation of the processor 12 or the display module 11. When the processor 12 executes an application stored in the memory 13, an image data signal and/or an input control signal may be transmitted to the display module 11, and the display module 11 may process the received signals to output image information through a display screen.

The power module 14 may include a power supply module, such as a power adapter or a battery device, and a power conversion module that converts power supplied by the power supply module to generate power required for the operation of the electronic apparatus 10.

At least one of the components of the electronic apparatus 10 may be included in a display device according to embodiments. In addition, among individual modules that are functionally included within a single module, some may be included in the display device while others may be provided separately from the display device. As an example, the display device may include the display module 11, and the processor 12, the memory 13, and the power module 14 may be provided as separate devices within the electronic apparatus 10 and may not be included in the display device.

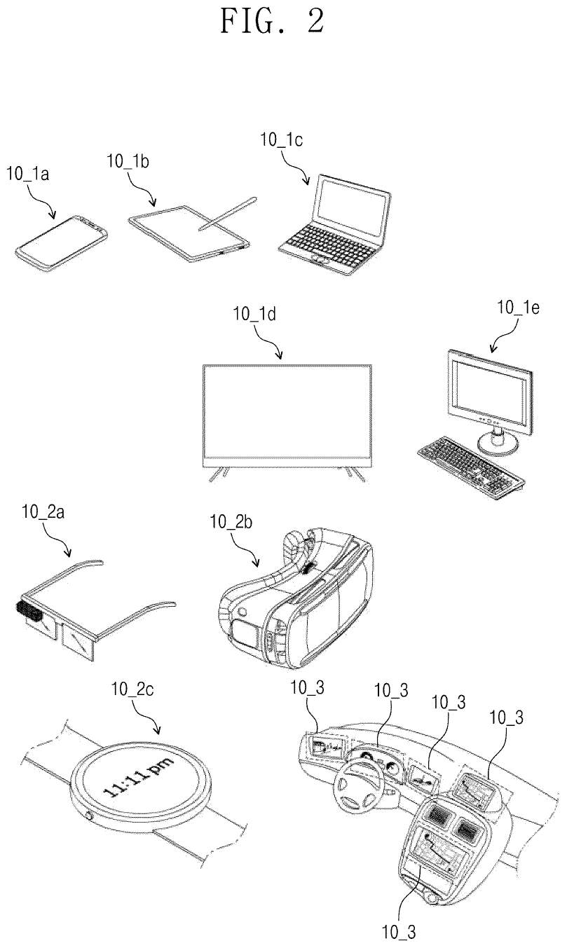

FIG. 2 is a view showing electronic apparatuses according to embodiments of the present disclosure.

Referring to FIG. 2, various electronic apparatuses to which the display device according to embodiments is applied may include an electronic apparatus for displaying images, such as a smartphone 10_1a, a tablet PC 10_1b, a laptop computer 10_1c, a television 10_1d, a desktop monitor 10_1e, etc., a wearable electronic apparatus including a display module, such as a smart glasses 10_2a, a head-mounted display 10_2b, a smartwatch 10_2c, etc., or an in-vehicle electronic apparatus 10_3 including a display module, such as an instrument panel, a center fascia, a dashboard-mounted center information display (CID), a room mirror display, etc.

Hereinafter, embodiments of the display device and the electronic apparatus including the display device of the present disclosure will be described with reference to accompanying drawings.

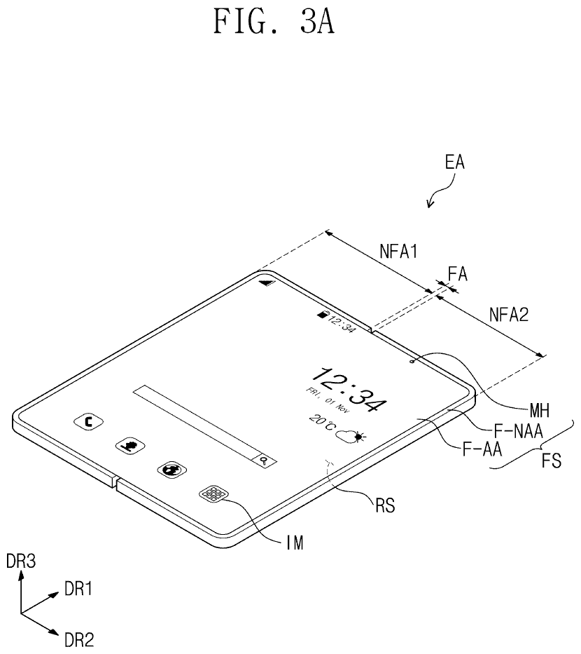

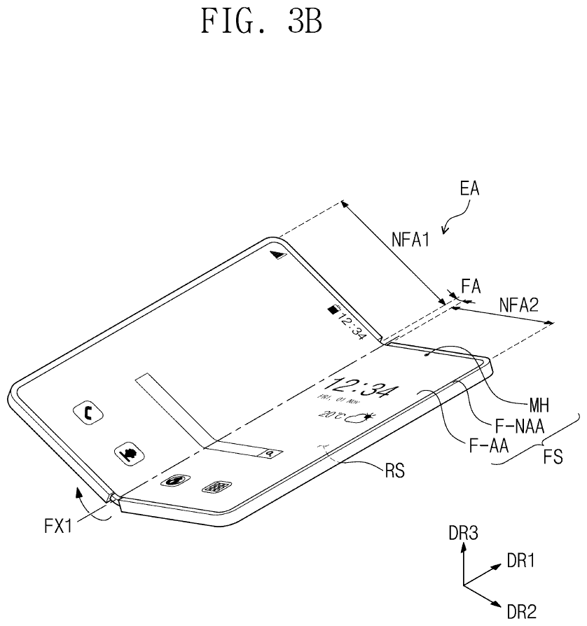

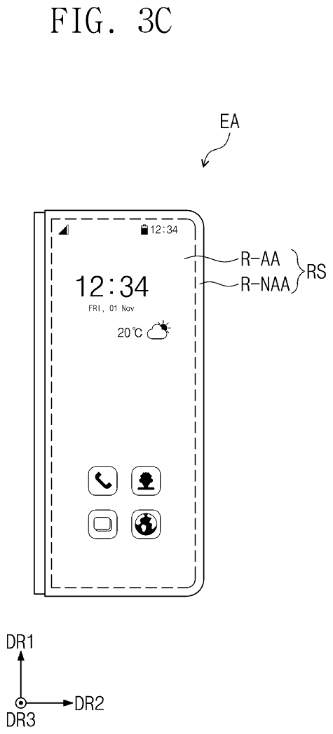

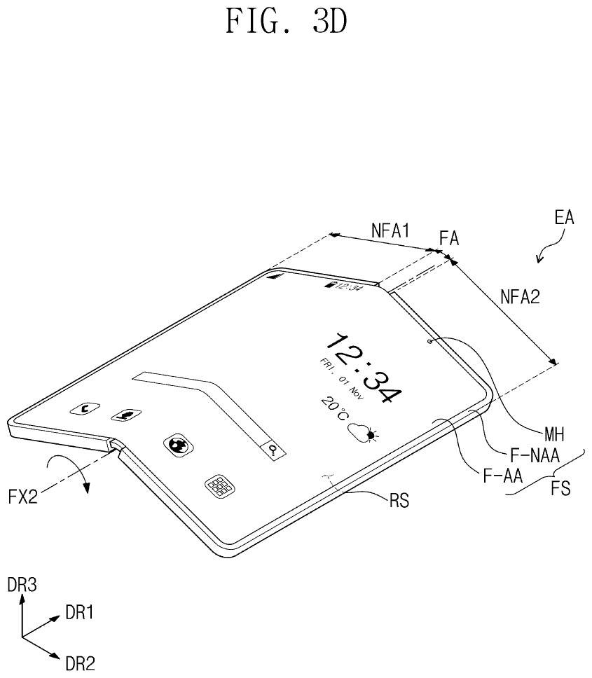

FIG. 3A is a perspective view showing an electronic apparatus EA in an unfolded state according to an embodiment of the present disclosure.

Referring to FIG. 3A, the electronic apparatus EA may be a device that is activated in response to electrical signals. As an example, the electronic apparatus EA may be a smartphone, a tablet computer, a car navigation unit, a game unit, or a wearable device, however, it should not be limited thereto or thereby. In FIG. 3A, the smartphone is shown as a representative example of the electronic apparatus EA.

The electronic apparatus EA may include a first display surface FS defined by a first direction DR1 and a second direction DR2 intersecting the first direction DR1. The electronic apparatus EA may provide an image IM to a user through the first display surface FS. The electronic apparatus EA may display the image IM through the first display surface FS, which is substantially parallel to each of the first direction DR1 and the second direction DR2, toward a third direction DR3. The image IM may include a video and a still image.

In the present disclosure, the first direction DR1 may be perpendicular to the second direction DR2, and the third direction DR3 may be a normal line direction with respect to a plane defined by the first direction DR1 and the second direction DR2. A thickness direction of the electronic apparatus EA may be substantially parallel to the third direction DR3. The thickness direction of the electronic apparatus EA may be assigned with the same reference numeral as the third direction DR3. A front surface (or upper surface) and a rear surface (or lower surface) may be opposite to each other in the third direction DR3, and a normal line direction of each of the front surface (or upper surface) and the rear surface (or lower surface) may be substantially parallel to the third direction DR3. The front surface (or upper surface) may indicate a surface adjacent to the first display surface FS, and the rear surface (or lower surface) may indicate a surface spaced apart from the first display surface FS. In addition, the rear surface (or lower surface) may indicate the surface closer to a second display surface RS described later. A cross-section refers to a flat surface parallel to the thickness direction DR3, and a plane refers to a flat surface perpendicular to the thickness direction DR3. The plane refers to a flat surface defined by the first direction DR1 and the second direction DR2.

In the present disclosure, directions indicated by the first, second, and third directions DR1, DR2, and DR3 may be relative to each other and may be changed to other directions.

The electronic apparatus EA may sense an external input applied from an outside thereof. The external input may include various forms of inputs provided from the outside of the electronic apparatus EA. For example, the external inputs may include an external input (e.g., hovering) applied in close proximity to, or at a selected distance from the electronic apparatus EA as well as a contact by a part of body (e.g., user's hand). In addition, the external inputs may be provided in the form of force, pressure, temperature, light, etc.

The electronic apparatus EA may include the first display surface FS and the second display surface RS. The first display surface FS may include a first active area F-AA, a first peripheral area F-NAA, and a sub-area MH. The second display surface RS may be defined as a surface that is opposite to at least a portion of the first display surface FS. That is, the second display surface RS may be defined as a portion of the rear surface of the electronic apparatus EA.

The first active area F-AA may be activated in response to the electrical signals. The image IM may be displayed through the first active area F-AA, and various external inputs may be sensed through the first active area F-AA.

The first peripheral area F-NAA may be defined adjacent to the first active area F-AA. The first peripheral area F-NAA may have a light transmittance lower than a light transmittance of the first active area F-AA. The first peripheral area F-NAA may have a selected color. The first peripheral area F-NAA may surround the first active area F-AA. Accordingly, the first active area F-AA may have a shape that is substantially defined by the first peripheral area F-NAA, however, this is merely an example. The first peripheral area F-NAA may be defined adjacent to only one side of the first active area F-AA or may be omitted.

An external object may be detected through the sub-area MH of the display surfaces FS and RS, or a sound signal, such as a voice, may be provided to the outside through the sub-area MH of the display surfaces FS and RS. Optical signals such as visible light or infrared light may travel through the sub-area MH.

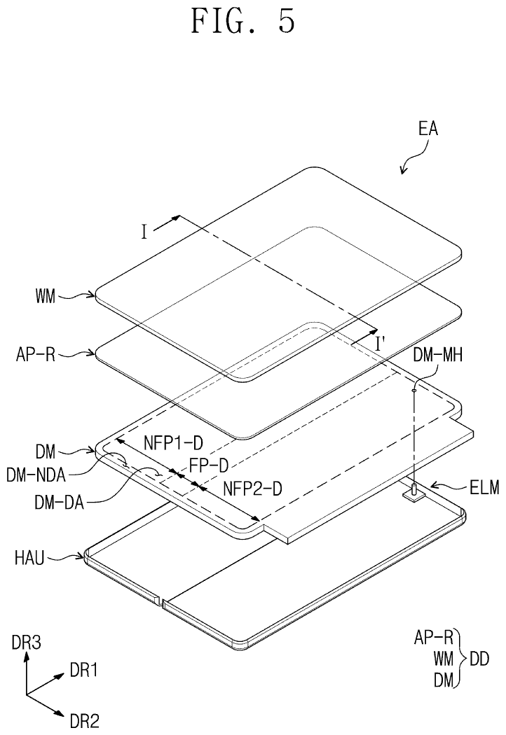

Various electronic modules ELM (refer to FIG. 5) may be disposed in the sub-area MH. For example, the electronic module ELM (refer to FIG. 5) may include at least one of a camera, a speaker, an optical sensor, and a thermal sensor. The electronic apparatus EA may include the electronic module ELM (refer to FIG. 5) that takes a picture of an external object using the visible light passing through the sub-area MH or determines whether an external object is approaching using the infrared light. In addition, the electronic module ELM (refer to FIG. 5) may include a plurality of components, however, it should not be limited to a particular embodiment.

The sub-area MH may be defined in the first active area F-AA, however, this is merely an example. As an example, the sub-area MH may be surrounded by the first peripheral area F-NAA or may be surrounded by the first active area F-AA and the first peripheral area F-NAA. FIG. 3A shows one sub-area MH, however, the sub-area MH may be provided in plural.

The electronic apparatus EA may include at least one folding area FA and a plurality of non-folding areas NFA1 and NFA2 extending from the folding area FA. As an example, a first non-folding area NFA1, the folding area FA, and a second non-folding area NFA2 may be defined along the second direction DR2. The second non-folding area NFA2 may be spaced apart from the first non-folding area NFA1 in the second direction DR2, and the folding area FA may be disposed between the first and second non-folding areas NFA1 and NFA2. For example, the first non-folding area NFA1 may be disposed adjacent to one side of the folding area FA in the second direction DR2, and the second non-folding area NFA2 may be disposed adjacent to the other side of the folding area FA in the second direction DR2.

FIG. 3A shows the structure in which the electronic apparatus EA includes one folding area FA as a representative example, however, the present disclosure should not be limited thereto or thereby, and the electronic apparatus EA may include a plurality of folding areas defined therein. As an example, the electronic device may include two or more folding areas and three or more non-folding areas arranged such that the folding area is interposed between the non-folding areas.

FIG. 3B is a perspective view showing a folding operation of the electronic apparatus EA according to an embodiment of the present disclosure. FIG. 3C is a plan view showing the electronic apparatus EA in a folded state according to an embodiment of the present disclosure. FIG. 3D is a perspective view showing a folding operation of the electronic apparatus EA according to an embodiment of the present disclosure. As used herein, the plan view is a view in a thickness direction (third direction DR3) of the window WM.

Referring to FIG. 3B, the electronic apparatus EA may be folded with respect to a first folding axis FX1 extending in the first direction DR1. When the electronic apparatus EA is folded, the folding area FA may have a selected curvature and a radius of curvature. The electronic apparatus EA may be inwardly folded (in-folding) with respect to the first folding axis FX1 to allow the first non-folding area NFA1 to face the second non-folding area NFA2 and the first display surface FS not to be exposed to the outside.

FIG. 3C is a plan view showing the electronic apparatus EA inwardly folded. Referring to FIG. 3C, the second display surface RS may be viewed by the user when the electronic apparatus EA is inwardly folded. In this case, the second display surface RS may include a second active area R-AA through which images are displayed. The second active area R-AA may be activated in response to electrical signals. The images may be displayed through the second active area R-AA, and various external inputs may be sensed through the second active area R-AA.

A second peripheral area R-NAA may be defined adjacent to the second active area R-AA. The second peripheral area R-NAA may have a light transmittance lower than a light transmittance of the second active area R-AA. The second peripheral area R-NAA may have a selected color. The second peripheral area R-NAA may surround the second active area R-AA. Although not shown in figures, the electronic apparatus EA may further include a sub-area in which an electronic module including various components is disposed in the second display surface RS.

Referring to FIG. 3D, the electronic apparatus EA may be folded with respect to a second folding axis FX2 extending in the first direction DR1. The electronic apparatus EA may be outwardly folded (out-folding) with respect to the second folding axis FX2 to allow the first display surface FS to be exposed to the outside. The electronic apparatus EA may be configured to repeat the in-folding operation or the out-folding operation from the unfolding operation, however, the present disclosure should not be limited thereto or thereby.

FIGS. 3A to 3D show the electronic apparatus EA folded with respect to one folding axis FX1 or FX2 as a representative example, however, the number of the folding axes and the number of non-folding areas should not be particularly limited. As an example, the electronic apparatus EA may be folded with respect to multiple folding axes to allow a portion of the first display surface FS to face a portion of the second display surface RS. In addition, the first and second folding axes FX1 and FX2 are shown as being parallel to long sides of the electronic apparatus EA in the above embodiments, however, the present disclosure should not be limited thereto or thereby. According to an embodiment, the first and second folding axes FX1 and FX2 may be substantially parallel to short sides of the electronic apparatus EA.

In the electronic apparatus EA, the first non-folding area NFA1 and the second non-folding area NFA2 may be defined as areas including the display surfaces FS and RS parallel to the plane defined by the first direction DR1 and the second direction DR2 in the unfolded state as shown in FIG. 3A, and the folding area FA may be defined as an area between the first non-folding area NFA1 and the second non-folding area NFA2. The folding area FA may include a curved portion that has a selected curvature in the folded state.

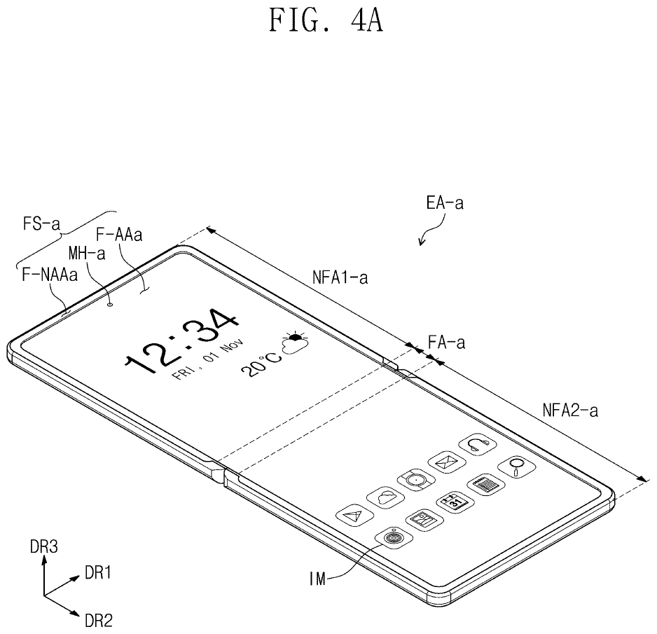

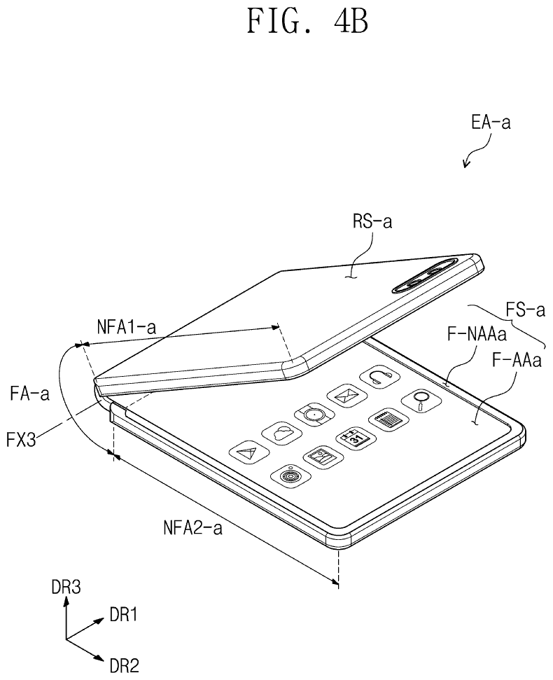

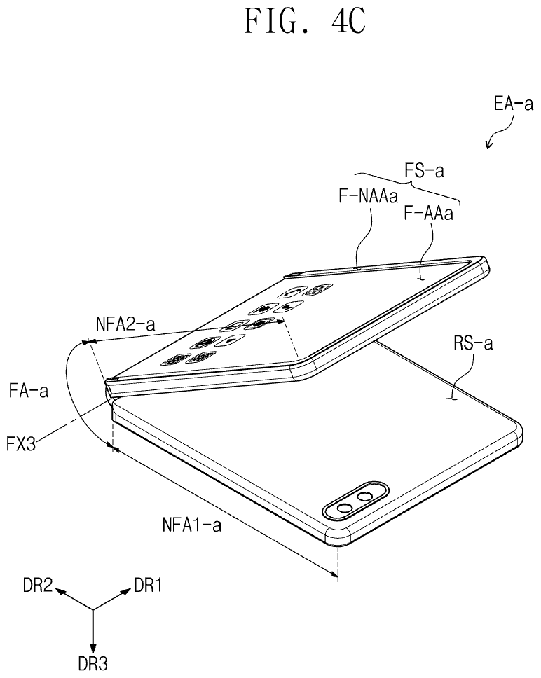

FIGS. 4A to 4C are perspective views showing an electronic apparatus EA-a according to an embodiment of the present disclosure. FIG. 4A is a perspective view showing the electronic apparatus EA-a in an unfolded state. FIGS. 4B and 4C are perspective views showing a folding operation of the electronic apparatus EA-a. FIG. 4B is a perspective view showing an in-folding operation of the electronic apparatus EA-a of FIG. 4A. FIG. 4C is a perspective view showing an out-folding operation of the electronic apparatus EA-a of FIG. 4A.

The electronic apparatus EA-a may be folded with respect to a third folding axis FX3 extending in a direction substantially parallel to the first direction DR1. Referring to FIGS. 4B and 4C, the direction in which the third folding axis FX3 extends may be substantially parallel to a direction in which a short side of the electronic apparatus EA-a extends.

The electronic apparatus EA-a may include a folding area FA-a, a first non-folding area NFA1-a adjacent to one side of the folding area FA-a, and a second non-folding area NFA2-a adjacent to the other side of the folding area FA-a. The first non-folding area NFA1-a may be spaced apart from the second non-folding area NFA2-a, and the folding area FA-a may be disposed between the first non-folding area NFA1-a and the second non-folding area NFA2-a.

The folding area FA-a may be an area that is folded with respect to the third folding axis FX3. When the electronic apparatus EA-a is folded, the folding area FA-a may have a selected curvature and a radius of curvature. The electronic apparatus EA-a may be inwardly folded (in-folding) to allow the first non-folding area NFA1-a to face the second non-folding area NFA2-a and a display surface FS-a not to be exposed to the outside.

Referring to FIG. 4A, the display surface FS-a may be viewed by the user when the electronic apparatus EA-a is in the unfolded state. Similar to the descriptions with reference to FIGS. 3A to 3D, the display surface FS-a of the electronic apparatus EA-a may include an active area F-AAa, a peripheral area F-NAAa, and a sub-area MH-a. An image IM may be displayed through the active area F-AAa, and various external inputs may be sensed through the active area F-AAa.

Referring to FIG. 4B, a rear surface RS-a may be viewed by the user when the electronic apparatus EA-a is inwardly folded. As an example, the rear surface RS-a may function as a second display surface through which images are displayed. In addition, the rear surface RS-a may include a sub-area in which an electronic module including various components is disposed.

Referring to FIG. 4C, the electronic apparatus EA-a may be outwardly folded (out-folding) with respect to the third folding axis FX3 to allow a portion of the rear surface RS-a, which overlaps the first non-folding area NFA1-a, to face another portion of the rear surface RS-a, which overlaps the second non-folding area NFA2-a.

FIG. 5 is an exploded perspective view showing the electronic apparatus EA of FIG. 3A according to an embodiment of the present disclosure. The following description on the electronic apparatus EA may be equally applied to the electronic apparatus EA-a shown in FIGS. 4A to 4C.

Referring to FIG. 5, the electronic apparatus EA may include the electronic module ELM and the display device DD. In addition, the electronic apparatus EA may further include a housing HAU. The display device DD may include a display module DM and a window WM disposed on the display module DM. A module area DM-MH may be defined through the display device DD, and the electronic module ELM may be disposed to correspond to the module area DM-MH.

The image IM (refer to FIG. 3A) generated by the display module DM may be provided to the user through the window WM. The window WM may be folded with respect to at least one folding axis FX1 or FX2 (refer to FIGS. 3B and 3D).

The display device DD may further include an upper adhesive layer AP-R. The upper adhesive layer AP-R may be disposed between the display module DM and the window WM. The display module DM may be coupled with the window WM by the upper adhesive layer AP-R. The upper adhesive layer AP-R may include a pressure sensitive adhesive (PSA), an optically clear adhesive (OCA) film, or an optically clear adhesive resin (OCR) layer.

The display module DM may display images in response to electrical signals. The display module DM may transmit or receive information about the external input. A display area DM-DA and a non-display area DM-NDA may be defined in the display module DM. In addition, the module area DM-MH may be defined through the display module DM.

The display area DM-DA may be defined as an area from which images provided by the display module DM are emitted. The display area DM-DA of the display module DM may correspond to at least a portion of the first active area F-AA (refer to FIG. 3A).

Driving circuits or driving lines to drive the display area DM-DA may be arranged in the non-display area DM-NDA. The non-display area DM-NDA may be defined adjacent to the display area DM-DA. As an example, the non-display area DM-NDA may surround the display area DM-DA, however, this is merely an example. According to an embodiment, the non-display area DM-NDA may be defined in various shapes, and should not be particularly limited.

The module area DM-MH may correspond to the sub-area MH shown in FIG. 3A. Optical signals may be applied through the module area DM-MH. The module area DM-MH may be defined in the display area DM-DA, however, the present disclosure should not be particularly limited.

The electronic module ELM may be disposed to correspond to the module area DM-MH. The electronic module ELM may be an electronic component that outputs or receives optical signals. As an example, the electronic module ELM may include a camera module and/or a proximity sensor. The camera module may take a picture of the external object through the module area DM-MH. However, the present disclosure should not be limited thereto or thereby, and the electronic module ELM may further include an internal module and/or an external module. The internal module may include a sensor module, an antenna module, and an audio output module. The external module may include a light module and a communication module.

The display module DM may include a folding display part FP-D and non-folding display parts NFP1-D and NFP2-D. The folding display part FP-D may correspond to the folding area FA (refer to FIG. 3A), and the non-folding display parts NFP1-D and NFP2-D may correspond to the non-folding areas NFA1 and NFA2 (refer to FIG. 3A).

The housing HAU may include a material with relatively high rigidity. As an example, the housing HAU may include a plurality of frames and/or plates including of a glass, plastic, or metal material. The housing HAU may provide an accommodation space. The display module DM may be accommodated in the accommodation space and may be protected from external impacts.

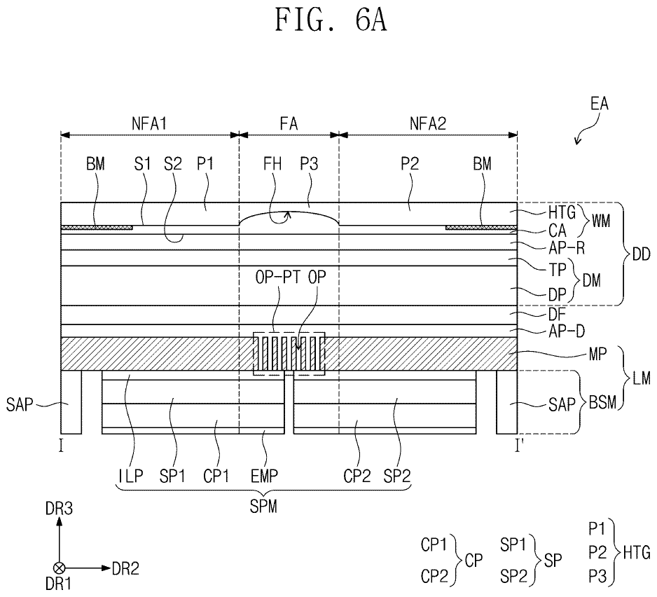

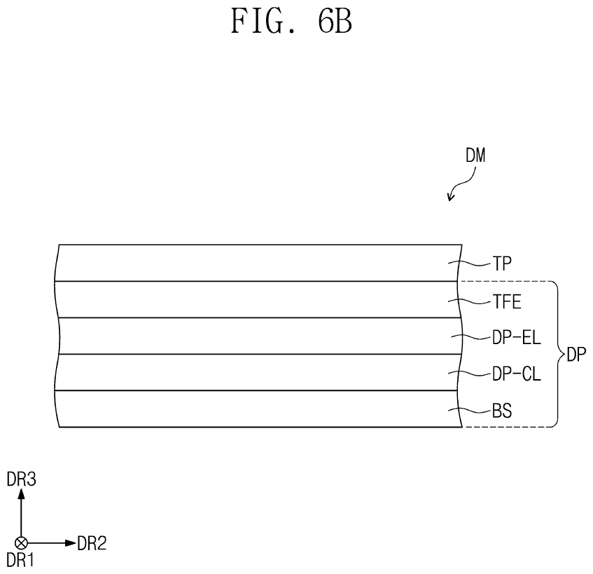

FIG. 6A is a cross-sectional view taken along line I-I′ of FIG. 5. FIG. 6A is a cross-sectional view showing the electronic apparatus EA. For the convenience of explanation, the housing HAU (refer to FIG. 5) is omitted in FIG. 6A.

Referring to FIG. 6A, the electronic apparatus EA may further include a lower module LM, a lower adhesive layer AP-D, and a lower protective film DF. The lower module LM, the lower adhesive layer AP-D, and the lower protective film DF may be disposed between the display device DD and the housing HAU (refer to FIG. 5).

The lower module LM may be disposed under the display module DM. The lower module LM may include a support plate MP and a lower support member BSM. The configuration of the lower module LM shown in FIG. 6A is an example, and a combination of components included in the lower module LM in the electronic apparatus EA may vary depending on a size of the electronic apparatus EA, a shape of the electronic apparatus EA, or operating characteristics of the electronic apparatus EA.

The support plate MP may include a metal material or a polymer material. As an example, the support plate MP may include stainless steel, aluminum, or an alloy thereof. A plurality of openings OP may be defined through the support plate MP. The support plate MP may include an opening pattern OP-PT through which the openings OP are defined. The opening pattern OP-PT may be formed in the folding area FA.

The lower support member BSM may include a support member SPM and a filling portion SAP. The support member SPM may overlap most of the portion of the display module DM in a plan view. The filling portion SAP may be disposed outside the support member SPM and may overlap an outer portion of the display module DM in a plan view.

The support member SPM may include at least one of a support layer SP, a cushion layer CP, a shielding layer EMP, and an interlayer adhesive layer ILP. The configuration of the support member SPM shown in FIG. 6A is merely an example, and the present disclosure should not be limited to that shown in FIG. 6A. As an example, one or more of the support layer SP, the cushion layer CP, the shielding layer EMP, and the interlayer adhesive layer ILP may be omitted, a stack order of the support layer SP, the cushion layer CP, the shielding layer EMP, and the interlayer adhesive layer ILP may be changed from that of FIG. 6A, or other components may be further added.

The support layer SP may include a metal material or a polymer material. The support layer SP may be disposed under the support plate MP. As an example, the support layer SP may be a thin metal substrate. The support layer SP may include a first sub-support layer SP1 and a second sub-support layer SP2 spaced apart from the first sub-support layer SP1 in the second direction DR2. The first sub-support layer SP1 and the second sub-support layer SP2 may be spaced apart from each other in a portion corresponding to the folding axes FX1 and FX2 (refer to FIGS. 3B and 3D). As the support layer SP includes the first sub-support layer SP1 and the second sub-support layer SP2 that are spaced apart from each other in the folding area FA, folding characteristics of the electronic apparatus EA may be improved.

The cushion layer CP may be disposed under the support layer SP. The cushion layer CP may prevent the support plate MP from being pressed and plastic-deformed by external impact and force. The cushion layer CP may improve an impact resistance of the electronic apparatus EA. The cushion layer CP may include a sponge, a foam, or an elastomer such as a urethane resin. In addition, the cushion layer CP may include at least one of an acrylic-based polymer, a urethane-based polymer, a silicone-based polymer, and an imide-based polymer, however, it should not be limited thereto or thereby.

The cushion layer CP may include a first sub-cushion layer CP1 and a second sub-cushion layer CP2 spaced apart from the first sub-cushion layer CP1 in the second direction DR2. The first sub-cushion layer CP1 and the second sub-cushion layer CP2 may be spaced apart from each other in an area corresponding to the folding axes FX1 and FX2 (refer to FIGS. 3B and 3D). As the cushion layer CP includes the first sub-cushion layer CP1 and the second sub-cushion layer CP2 that are spaced apart from each other in the folding area FA, the folding characteristics of the electronic apparatus EA may be improved.

The shielding layer EMP may be an electromagnetic shielding layer or a heat dissipation layer. In addition, the shielding layer EMP may perform a function of an adhesive layer.

The interlayer adhesive layer ILP may attach the support plate MP to the support member SPM. The interlayer adhesive layer ILP may be provided in the form of an adhesive resin layer or an adhesive tape. FIG. 6A shows a structure in which the interlayer adhesive layer ILP is divided into two portions spaced apart from each other in an area corresponding to the folding axes FX1 and FX2 (refer to FIGS. 3B and 3D), however, the present disclosure should not be limited thereto or thereby. The interlayer adhesive layer ILP may be provided as a single layer without being divided into portions in the area corresponding to the folding axes FX1 and FX2 (refer to FIGS. 3B and 3D).

The filling portion SAP may be disposed outside the support layer SP and the cushion layer CP. The filling portion SAP may be disposed between the support plate MP and the housing HAU (refer to FIG. 5). The filling portion SAP may be filled in a space between the support plate MP and the housing HAU (refer to FIG. 5) and may fix the support plate MP.

The lower protective film DF may be disposed between the display module DM and the support plate MP. The lower protective film DF may be disposed under the display module DM and may protect a rear surface of the display module DM. The lower protective film DF may overlap the entirety of the display module DM. The lower protective film DF may include a polymer material. As an example, the lower protective film DF may be a polyimide film or a polyethylene terephthalate film, however, this is merely an example, and the lower protective film DF should not be limited thereto or thereby.

The lower adhesive layer AP-D may be disposed between the support plate MP and the lower protective film DF. The support plate MP and the lower protective film DF may be coupled with each other by the lower adhesive layer AP-D. The lower adhesive layer AP-D may include a pressure sensitive adhesive (PSA), an optically clear adhesive (OCA) film, or an optically clear adhesive resin (OCR) layer, however, the present disclosure should not be limited thereto or thereby. According to an embodiment, the lower adhesive layer AP-D may be omitted.

The display module DM may include a display panel DP and an input sensing part TP disposed on the display panel DP. The display panel DP may substantially generate images. The display panel DP may be folded with respect to the folding axes FX1 and FX2 (refer to FIGS. 3B and 3D).

The input sensing part TP may sense an external input, may convert the sensed input to an input signal, and may provide the input signal to the display panel DP. As an example, the input sensing part TP may be a touch sensing part that senses a touch event. The input sensing part TP may sense a direct touch by a user, an indirect touch by a user, a direct touch by an object, or an indirect touch by an object.

The input sensing part TP may sense at least one of a position of a touch event applied from the outside and an intensity (pressure) of the touch event applied from the outside. The input sensing part TP may have various structures or may include various materials, and it should not be particularly limited. As an example, the input sensing part TP may sense the external input in a capacitive manner. The display panel DP may receive the input signal from the input sensing part TP and may generate the image corresponding to the input signal.

The window WM may include a substrate HTG, a coating layer CA disposed under the substrate HTG, and a black matrix BM disposed under the substrate HTG.

The substrate HTG may include an optically transparent insulating material. The substrate HTG may include a glass material.

An upper surface of the substrate HTG may be flat. Accordingly, an uppermost surface of the display device DD may be flat. The image IM (refer to FIG. 3A) generated by the display module DM may be provided to the user through the window WM.

According to the present disclosure, the upper surface of the substrate HTG may be flat. The display device DD may have improved surface quality. The image IM (refer to FIG. 3A) of a higher quality may be provided to the user. Accordingly, the display quality of the electronic apparatus EA may be improved.

The substrate HTG may include a first portion P1 overlapping the first non-folding area NFA1, a second portion P2 overlapping the second non-folding area NFA2, and a third portion P3 overlapping the folding area FA and having a thickness smaller than each of thicknesses of the first portion P1 and the second portion P2. A lower surface of the third portion P3 may have a selected curvature. The substrate HTG may have a concave shape in the third direction DR3 in the folding area FA toward the upper surface of the substrate HTG.

A folding groove FH may be defined in the lower surface of the third portion P3. The folding groove FH may be formed by removing a portion of the third portion P3 from the lower surface. In FIG. 6A, the folding groove FH is shown as a shape corresponding to a portion of a semicircle, however, the shape of the folding groove FH according to the present disclosure should not be limited thereto or thereby. As an example, the folding groove FH may have a shape corresponding to a portion of a trapezoid.

The third portion P3 may have the thickness smaller than the thickness of the first portion P1 and the thickness of the second portion P2.

According to the present disclosure, since the thickness of the third portion P3 is smaller than the thickness of the first portion P1 and the thickness of the second portion P2, the window WM may be easily folded in the folding area FA when the electronic apparatus EA is folded. As the thickness of the first portion P1 and the thickness of the second portion P2 are greater than the thickness of the third portion P3, the first portion P1 and the second portion P2 may have greater rigidity than the third portion P3. Accordingly, the reliability of the electronic apparatus EA may be improved.

The coating layer CA may be disposed under the substrate HTG. The coating layer CA may include a first surface S1 adjacent to the substrate HTG and a second surface S2 spaced apart from the substrate HTG, and the first surface S1 may be disposed between the substrate HTG and the second surface S2. A portion of the first surface S1 may have a convex shape in the third direction DR3 toward the substrate HTG. The convex shape of the portion of the first surface S1 may be a complementary shape of the concave shape of the substrate HTG. Accordingly, the portion of the first surface S1 may be disposed in the folding groove FH. The second surface S2 may be in direct contact with the upper adhesive layer AP-R.

The coating layer CA may include an acrylic resin, an epoxy resin, a silicone resin, a urethane resin, a urethane acrylic resin, a hybrid sol-gel, and a siloxane resin. The window WM with the above structure may have improved impact resistance through the coating layer CA while maintaining optical properties and design properties of the substrate HTG.

The black matrix BM may be disposed between the substrate HTG and the coating layer CA. In the plan view, the black matrix BM may overlap the non-display area DM-NDA (refer to FIG. 5). The black matrix BM may include a material that blocks light. The black matrix BM may absorb light incident thereto from the outside.

FIG. 6B is a cross-sectional view showing a portion of the display module DM according to an embodiment of the present disclosure.

Referring to FIG. 6B, the display module DM may include the display panel DP and the input sensing part TP disposed on the display panel DP. The display panel DP may have a configuration that substantially generates the image.

The display panel DP may include a base layer BS, a circuit layer DP-CL, a display element layer DP-EL, and an encapsulation layer TFE, which are sequentially stacked. Different from the structure shown in FIG. 6B, a separate member may be further disposed between two layers adjacent to each other among the base layer BS, the circuit layer DP-CL, the display element layer DP-EL, and the encapsulation layer TFE.

The base layer BS may provide a base surface on which the circuit layer DP-CL is disposed. The base layer BS may be a flexible substrate that is bendable, foldable, or rollable. The base layer BS may be a glass substrate, a metal substrate, or a polymer substrate, however, it should not be limited thereto or thereby. According to an embodiment, the base layer BS may be an inorganic layer, an organic layer, or a composite material layer.

The circuit layer DP-CL may be disposed on the base layer BS. The circuit layer DP-CL may include an insulating layer, a semiconductor pattern, a conductive pattern, and a signal line. The display element layer DP-EL may be disposed on the circuit layer DP-CL. The display element layer DP-EL may include a light emitting element (not shown). As an example, the light emitting element may include an organic light emitting material, an inorganic light emitting material, an organic-inorganic light emitting material, a quantum dot, or a quantum rod. As an example, the light emitting element may include a micro-LED or a nano-LED.

The encapsulation layer TFE may be disposed on the display element layer DP-EL. The encapsulation layer TFE may protect the display element layer DP-EL from moisture, oxygen, and a foreign substance such as dust particles. The encapsulation layer TFE may include at least one inorganic layer. As an example, the encapsulation layer TFE may include an inorganic layer, an organic layer, and an inorganic layer, which are sequentially stacked.

The input sensing part TP may be disposed on the display panel DP. The input sensing part TP may be disposed directly on the encapsulation layer TFE, however, the present disclosure should not be limited thereto or thereby. According to an embodiment, an adhesive member may be disposed between the input sensing part TP and the display panel DP.

In the present disclosure, the expression “one component is disposed/provided/formed directly on another component” means that no third component is disposed between the one component and the another component. For example, when one component is “directly disposed/provided/formed” on another component, it means that the one component and the another component are in “contact” with each other.

The input sensing part TP may sense the external input, may convert the sensed external input to the input signal, and may provide the input signal to the display panel DP. As an example, the input sensing part TP may be the touch sensing part that senses a touch event. The input sensing part TP may sense a direct touch by a user, an indirect touch by a user, a direct touch by an object, or an indirect touch by an object.

The input sensing part TP may sense at least one of the position of the touch event applied from the outside and the intensity (pressure) of the touch event applied from the outside. The input sensing part TP may have various structures or may include various materials, and it should not be particularly limited. As an example, the input sensing part TP may sense the external input in the capacitive manner. The display panel DP may receive the input signal from the input sensing part TP and may generate the image corresponding to the input signal.

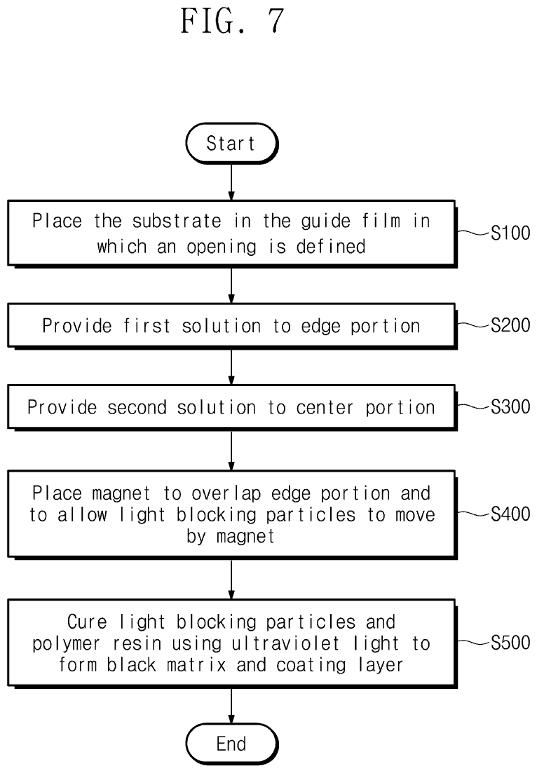

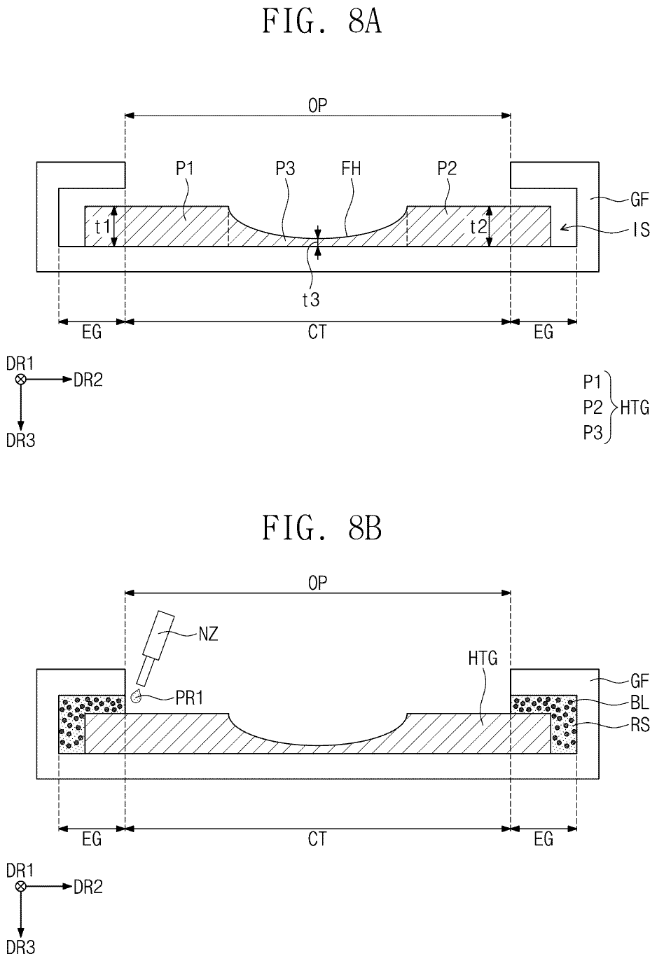

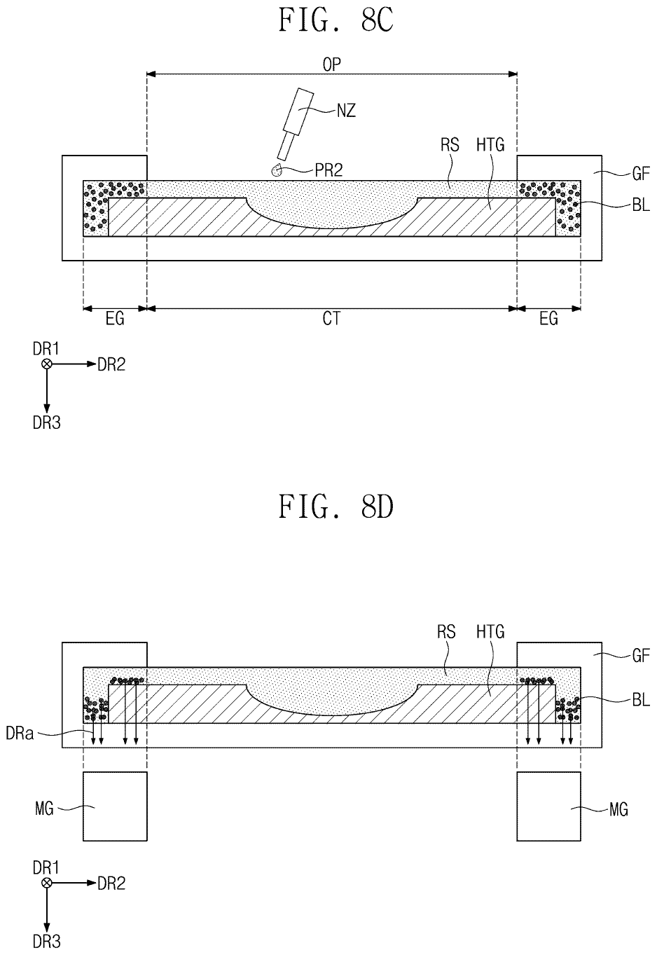

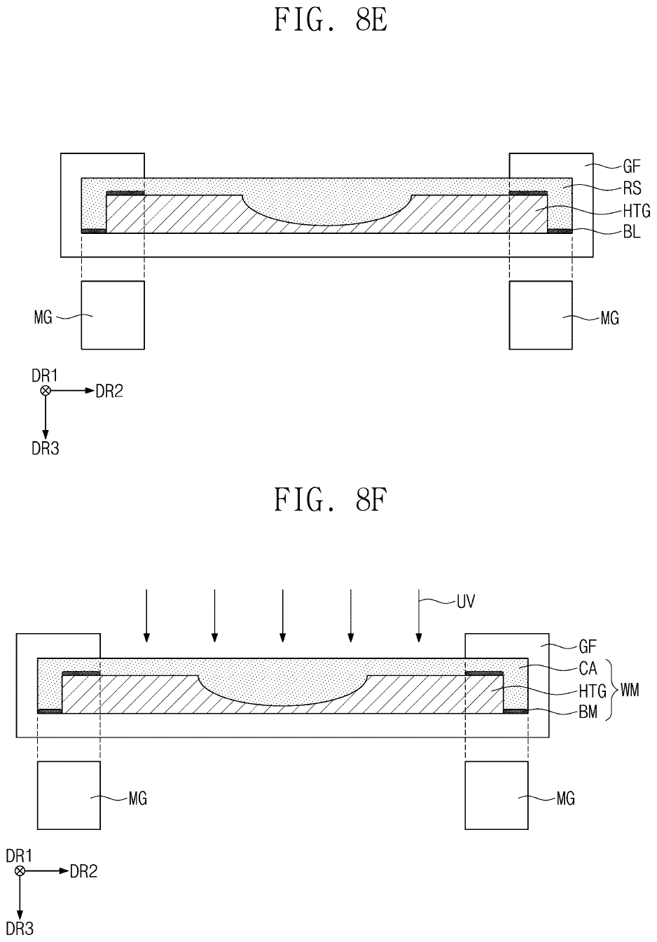

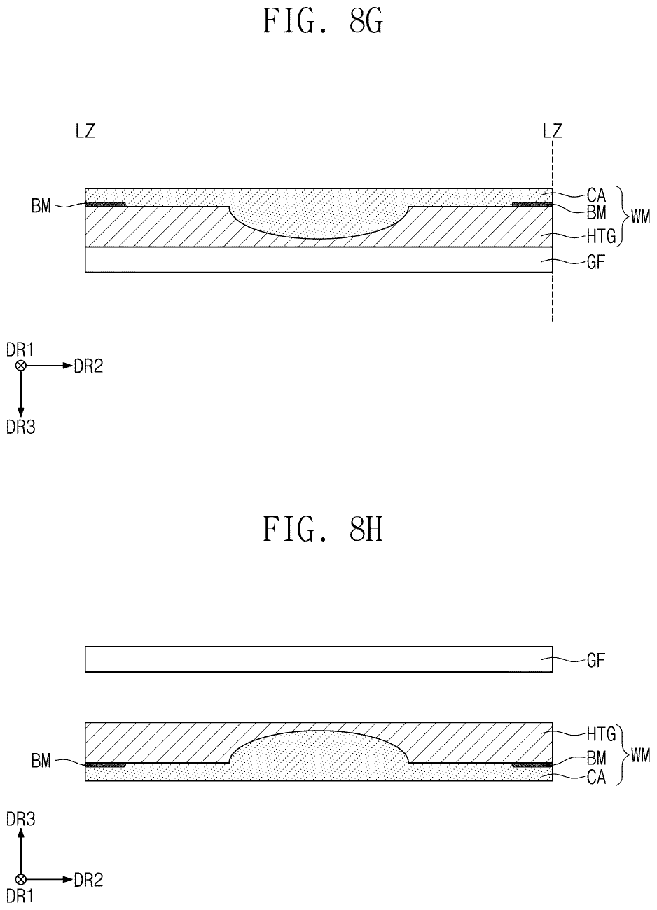

FIG. 7 is a flowchart showing a method of manufacturing the window according to an embodiment of the present disclosure. FIGS. 8A to 8G are views schematically showing processes of manufacturing the window according to an embodiment of the present disclosure. In FIGS. 8A to 8G, the same reference numerals denote the same elements in FIG. 6A, and thus, detailed descriptions of the same elements will be omitted. FIGS. 8A to 8G, 9A, 9B, 11A and 11B are upside down figures with respect to FIG. 6A.

The window WM may be manufactured according to the method of manufacturing the window described with reference to FIGS. 7 and 8A to 8G.

The manufacturing method of the window may include placing the substrate HTG in a guide film GF accommodating the substrate HTG and provided with an opening OP, which is defined through the guide film GF to overlap a portion of the substrate HTG in the plan view (S100), providing a first solution PR1, which contains a light blocking particle BL and a polymer resin RS, to an edge portion EG of an inner space IS of the guide film GF where the inner space is divided into a center portion CT overlapping the opening OP in the plan view and the edge portion EG, which is outside the center portion CT (S200), providing a second solution PR2, which contains a polymer resin RS, to the center portion CT (S300), placing a magnet MG to overlap the edge portion EG in the plan view to allow the light blocking particle BL to move by the magnet MG (S400), curing the light blocking particle BL and the polymer resin RS using an ultraviolet light to form the black matrix BM and the coating layer CA (S500). The window manufacturing method may further include partially cutting the edge portion EG using a laser beam, turning over the substrate HTG and the coating layer CA, and removing the guide film GF.

Referring to FIGS. 7 and 8A, the substrate HTG may be placed in the guide film GF (s100).

The guide film GF may accommodate the substrate HTG. The opening OP may be defined through an upper portion of the guide film GF.

The inner space IS may be defined in the guide film GF. In the plan view, the edge portion EG surrounding the substrate HTG and the center portion CT overlapping the opening OP in a plan view may be defined in the inner space IS.

The guide film GF may include a transparent material that transmits the ultraviolet light. The guide film GF may transmit a wavelength of about 365 nanometers (nm). The guide film GF may include polyethylene terephthalate (PET) and polycarbonate (PC).

The substrate HTG may be disposed in the inner space IS to allow the folding groove FH to face the opening OP. The substrate HTG may be coupled with the guide film GF.

The first portion P1 may have a first thickness t1. The second portion P2 may have a second thickness t2. The third portion P3 may have a third thickness t3.

The first thickness t1 and the second thickness t2 may be the same as each other. The third thickness t3 may be smaller than each of the first thickness t1 and the second thickness t2.

According to the present disclosure, since the third thickness t3 is smaller than each of the first thickness t1 and the second thickness t2, the window WM may be easily folded in the folding area FA when the electronic apparatus EA is folded. As the first thickness t1 and the second thickness t2 are greater than the third thickness t3, the first portion P1 and the second portion P2 may have rigidity greater than the third portion P3. Therefore, the reliability of the electronic apparatus EA may be improved.

The first solution PR1 containing the light blocking particle BL and the polymer resin RS may be provided to the edge portion EG (S200). The first solution PR1 may be provided through a nozzle NZ.

The light blocking particle BL may have ferromagnetism and light blocking properties. The light blocking particle BL may include Fe, Co, Ni, Mn, Fe₂O₃, or Fe₃O₄. The light blocking particle BL may be formed by coating a first material having the light blocking properties on a first portion having the ferromagnetism. As an example, since iron (Fe) does not have the light blocking properties, the light blocking particle BL may be formed by coating the first material on the iron (Fe). However, this is merely an example, and according to another embodiment, the light blocking particle BL may inherently have both light blocking properties and ferromagnetism. As an example, manganese (Mn) may inherently have both light blocking properties and ferromagnetism.

The light blocking particle BL may be arranged in the edge portion EG.

The polymer resin RS may include at least one of a urethane acrylate-based resin, an epoxy-based resin, and a silicone-based resin. The polymer resin RS may be a photocurable material that is cured by light.

Referring to FIGS. 7 and 8C, the second solution PR2 containing the polymer resin RS may be provided to the center portion CT (S300). The second solution PR2 may be provided through the nozzle NZ. The polymer resin RS may include at least one of a urethane acrylate-based resin, an epoxy-based resin, and a silicone-based resin.

The first solution PR1 (refer to FIG. 8B) and the second solution PR2 may include the same polymer resin RS. That is, the first solution PR1 (refer to FIG. 8B) may further include the light blocking particle BL compared to the second solution PR2.

Referring to FIGS. 7 and 8D, the magnet MG may be placed to overlap the edge portion EG in a plan view, and the light blocking particle BL may move by the magnet MG (S400).

The magnet MG may be placed under the guide film GF. In the plan view, the magnet MG may overlap the edge portion EG in a plan view (refer to FIG. 8C). The magnet MG may be spaced apart from the guide film GF in the third direction DR3.

The magnet MG may apply magnetic force to the first solution PR1. The magnet MG may change the direction of the magnetic force to move the light blocking particle BL to a desired location. The black matrix BM (refer to FIG. 8F) may be formed by the moved light blocking particle BL. This will be described later.

The magnet MG may include a solenoid device made by winding a copper wire around an electrically insulated and magnetically non-magnetic cylindrical tube, a flat type standard magnet or an axial type standard magnet, and an electromagnet including a yoke with an iron core, a coil, and a cooling system, and so forth.

The magnetic field may be applied in a direction parallel to the third direction DR3 by the magnet MG. The light blocking particle BL may be provided in plural. The light blocking particles BL having the ferromagnetism may move in a movement direction DRa by the magnetic field, and a concentration of the light blocking particles BL may increase along the third direction DR3 in the first solution PR1. In this case, since the polymer resin RS is not ferromagnetic, the polymer resin RS is not affected by the magnetic field.

Referring to FIGS. 7 and 8E, a concentration gradient may be formed in the first solution PR1. That is, the concentration of the light blocking particles BL may increase along the third direction DR3.

The light blocking particles BL may be arranged to overlap the edge portion EG (refer to FIG. 8C) in the plan view.

The light blocking particles BL may be arranged between the substrate HTG and the polymer resin RS in one area of the edge portion EG (refer to FIG. 8C). The light blocking particles BL arranged in the one area of the edge portion EG (refer to FIG. 8C) may cover the substrate HTG. The light blocking particles BL arranged in the one area of the edge portion EG (refer to FIG. 8C) may be in contact with the substrate HTG.

The light blocking particles BL may be arranged between the guide film GF and the polymer resin RS in the other area of the edge portion EG (refer to FIG. 8C).

Referring to FIGS. 7 and 8F, the light blocking particles BL and the polymer resin RS may be cured to form the black matrix BM.

When the magnet MG is placed under the guide film GF, the direction of the magnetic field may be the third direction DR3, and the light blocking particles BL having the ferromagnetism may move in the movement direction DRa (refer to FIG. 8D). When the substrate HTG is not present between the first solution PR1 and the magnet MG overlapping the edge portion EG (refer to FIG. 8C) in a plan view, the light blocking particles BL may move to the movement direction DRa (refer to FIG. 8D) in the first solution PR1 and may be arranged in the same plane as a lower surface of the substrate HTG.

Referring to FIGS. 7, 8E, and 8F, the light blocking particles BL and the polymer resin RS may be cured by the ultraviolet light UV to form the black matrix BM and the coating layer CA (S500).

The polymer resin RS may be the photocurable material that is cured by light. The curing process may be performed by irradiating the ultraviolet light after the light blocking particles BL move by the magnetic field. Therefore, the light blocking particles BL may be placed at the desired location by changing the direction of the magnetic force, and the black matrix BM may be formed through the curing process.

Different from the present disclosure, in a case where a black matrix and a coating layer are formed by printing and curing the black matrix and then coating and curing a polymer resin, two curing processes are required. However, according to the present disclosure, the light blocking particles BL and the polymer resin RS may be cured by the ultraviolet light UV to simultaneously form the black matrix BM and the coating layer CA. Accordingly, the window manufacturing process may be effectively simplified.

In addition, according to the present disclosure, the black matrix BM and the coating layer CA may be formed simultaneously by curing the light blocking particles BL and the polymer resin RS using the ultraviolet light UV. Therefore, the swelling phenomenon and the void phenomenon that may occur when the black matrix BM is formed before the coating layer CA may be prevented or eliminated. The swelling phenomenon may occur when the black matrix expands or sags due to gravity, and the void phenomenon may occur when the coating layer is formed due to a step difference in the black matrix. The black matrix BM may be prevented from being delaminated. Accordingly, the reliability of the window manufacturing method and the window WM (refer to FIG. 6A) may be improved.

Referring to FIGS. 7 and 8G, the edge portion EG (refer to FIG. 8C) may be partially cut by laser cutting process. In FIG. 8G, the laser beam LZ is shown as being irradiated in the third direction DR3 along a side of the substrate HTG as a representative example, but the cut range of the edge portion EG (refer to FIG. 8C) by the laser cutting according to the embodiment of the present disclosure should not be limited thereto or thereby. As an example, in the plan view, the laser beam LZ may be irradiated in the third direction DR3 to an area in which the black matrix BM is disposed and between the coating layer CA and the substrate HTG.

Referring to FIGS. 7 and 8H, the window manufacturing method according to the present disclosure may further include the turning over of the substrate HTG and the coating layer CA and the removing of the guide film GF.

In the turning over of the substrate HTG and the coating layer CA, the substrate HTG may be disposed on the coating layer CA, and the black matrix BM may be disposed between the substrate HTG and the coating layer CA in the third direction DR3. FIG. 8H shows an example of the window WM in which the positions of the substrate HTG and the coating layer CA are reversed compared to the window WM shown in FIG. 8G. The window WM may be attached to the display module DM (refer to FIG. 6A). The adhesive layer AP-R (refer to FIG. 6A) may be disposed between the window WM and the display module DM (refer to FIG. 6A).

Different from the present disclosure, when a protective layer is present on an upper surface of a substrate, a black matrix may be formed by a micro dry process decoration (MDD). However, according to the present disclosure, the upper surface of the substrate HTG may be flat without a separate protective layer. The surface quality of the display device DD may be improved. The image IM (refer to FIG. 3A) with high quality may be provided to the user.

In addition, different from the present disclosure, when the black matrix is formed by the micro dry process decoration (MDD), the substrate HTG may be damaged, and when the black matrix is formed by other printing processes, the swelling phenomenon or the void phenomenon may occur. However, according to the window manufacturing method of the present disclosure, the black matrix BM and the coating layer CA may be simultaneously formed using the first solution PR1 (refer to FIG. 8B) and the second solution (refer to FIG. 8C) without using the above described processes. Accordingly, the window manufacturing method may be effectively simplified. The swelling phenomenon or the void phenomenon may be effectively prevented from occurring. Therefore, the reliability of the window manufacturing method and the window WM may be improved.

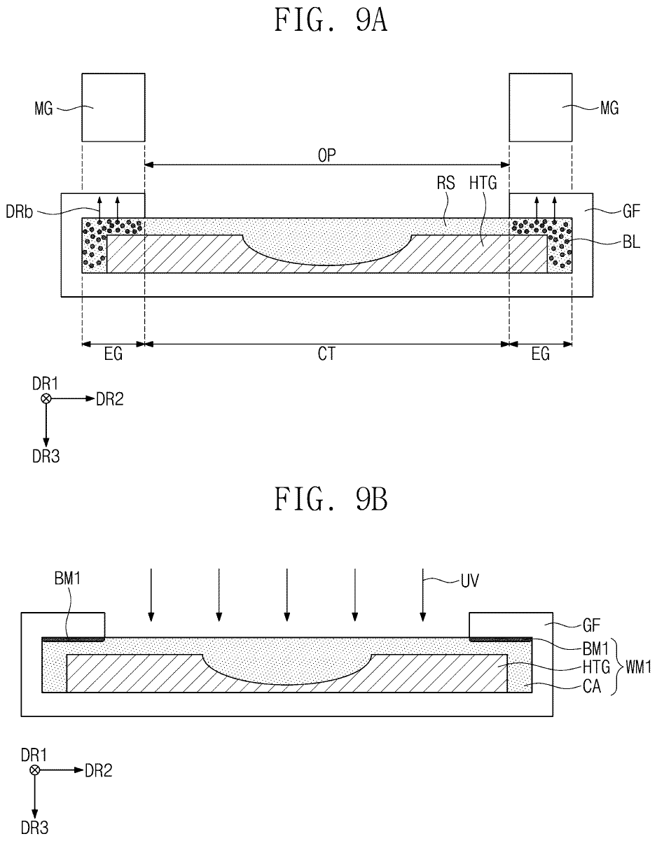

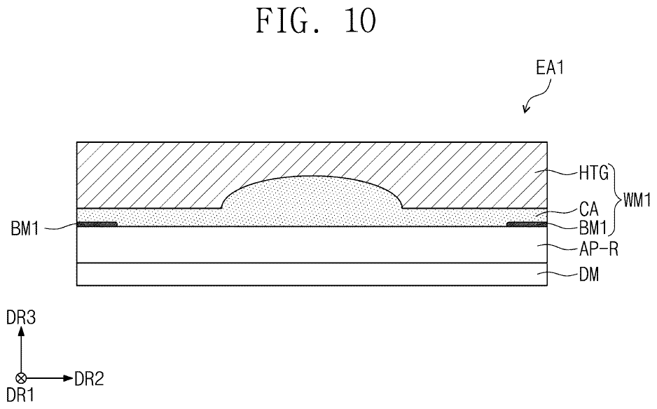

FIG. 9A is a view showing a process of manufacturing a window according to an embodiment of the present disclosure. In FIG. 9A, the same reference numerals denote the same elements in FIG. 8D, and thus, detailed descriptions of the same elements will be omitted.

Referring to FIG. 9A, a magnet MG may be disposed on a guide film GF. In this case, a direction of magnetic field may be opposite to the third direction DR3. Light blocking particles BL having ferromagnetism may move in a movement direction DRb. The light blocking particles BL may be spaced apart from a substrate HTG and may be in contact with the guide film GF.

FIG. 9B is a view showing a process of manufacturing the window according to an embodiment of the present disclosure. In FIG. 9B, the same reference numerals denote the same elements in FIG. 8F, and thus, detailed descriptions of the same elements will be omitted.

Referring to FIGS. 9A and 9B, the light blocking particles BL and a polymer resin RS may be cured by ultraviolet light UV to form a black matrix BM1 and a coating layer CA.

The black matrix BM1 may be disposed on the coating layer CA. The black matrix BM1 may be spaced apart from the substrate HTG, and the coating layer CA may be disposed between the black matrix BM1 and the substrate HTG.

Then, the window WM1 may be partially cut by laser cutting and may be manufactured through turning over the substrate HTG and the coating layer CA and removing the guide film GF.

FIG. 10 is a cross-sectional view showing a portion of an electronic apparatus according to an embodiment of the present disclosure. In FIG. 10, contents that are the same as the descriptions with reference to FIG. 6A will not be repeated, and the focus will be on explaining the differences.

Referring to FIG. 10, the electronic apparatus EA1 may include a window WM1, an adhesive layer AP-R, and a display module DM. The adhesive layer AP-R may be disposed between the window WM1 and the display module DM.

The window WM1 may include a substrate HTG, a coating layer CA, and a black matrix BM1. The black matrix BM1 may be in direct contact with the adhesive layer AP-R.

Compared to the window WM shown in FIG. 6A (refer to FIG. 6A), the window WM1 shown in FIG. 10 has a difference in the position where the black matrix BM1 is placed. The black matrix BM1 may be disposed between the coating layer CA and the adhesive layer AP-R.

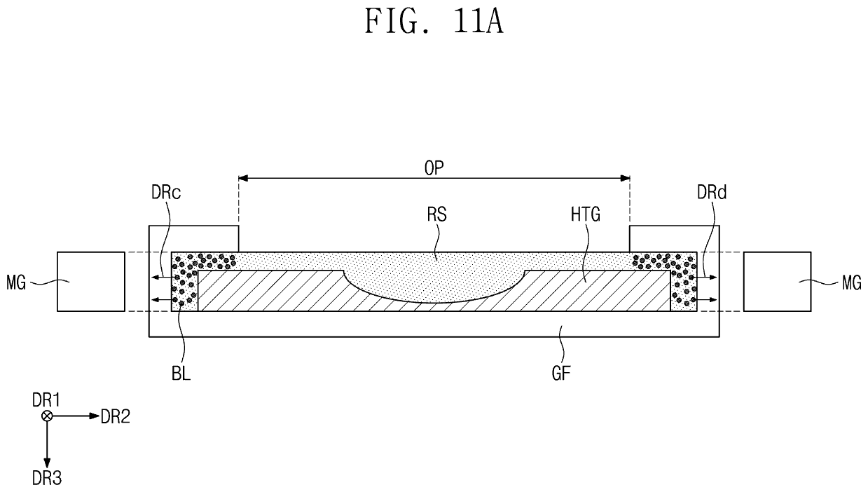

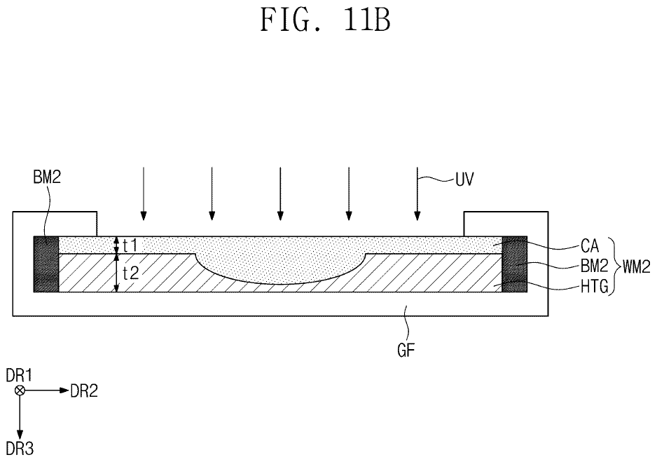

FIG. 11A is a view showing a process of manufacturing a window according to an embodiment of the present disclosure. In FIG. 11A, the same reference numerals denote the same elements in FIG. 8D, and thus, detailed descriptions of the same elements will be omitted.

Referring to FIG. 11A, when a magnet MG is disposed on side surfaces of a guide film GF, a direction of magnetic field may be the second direction DR2 or may be opposite to the second direction DR2. Light blocking particles BL having ferromagnetism may move in a first movement direction DRc or a second movement direction DRd. The light blocking particles BL may be disposed on side surfaces of a substrate HTG and side surfaces of a coating layer CA.

FIG. 11B is a view showing a process of manufacturing the window according to an embodiment of the present disclosure. In FIG. 11B, the same reference numerals denote the same elements in FIG. 8F, and thus, detailed descriptions of the same elements will be omitted.

Referring to FIGS. 11A and 11B, the light blocking particles BL and a polymer resin RS may be cured by ultraviolet light UV to form a black matrix BM2 and the coating layer CA.

A sum of a thickness t1 of the substrate HTG overlapping a center portion (refer to CT of FIG. 8C) in a plan view and a thickness t2 of the coating layer CA may be substantially the same as a thickness of the black matrix BM2. In the present disclosure, the term “substantially the same” means both cases where the physical measurements are exactly identical and cases where the difference falls within the allowable range (e.g., 10%) of process errors.

The black matrix BM2 may be disposed adjacent to the side surface of the substrate HTG and the side surface of the coating layer CA. In the plan view, the black matrix BM2 may not overlap the substrate HTG in a plan view.

Then, the window WM2 may be partially cut by laser cutting and may be manufactured through turning over the substrate HTG and the coating layer CA and removing the guide film GF.

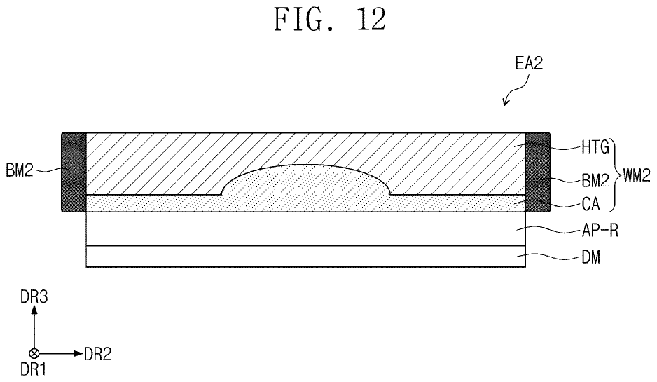

FIG. 12 is a cross-sectional view showing a portion of an electronic apparatus according to an embodiment of the present disclosure. In FIG. 12, contents that are the same as the descriptions with reference to FIG. 6A will not be repeated, and the focus will be on explaining the differences.

Referring to FIG. 12, the electronic apparatus EA2 may include a window WM2, an adhesive layer AP-R, and a display module DM. The adhesive layer AP-R may be disposed between the window WM2 and the display module DM.

The window WM2 may include a substrate HTG, a coating layer CA, and a black matrix BM2. The black matrix BM2 may be disposed on side surfaces of each of the substrate HTG and the coating layer CA.

Compared to the window WM shown in FIG. 6A (refer to FIG. 6A), the window WM2 shown in FIG. 12 has a difference in the position where the black matrix BM2 is placed. The black matrix BM2 may be disposed adjacent to the side surfaces of each of the substrate HTG and the coating layer CA. In the plan view, the black matrix BM2 may not overlap the display module DM in a plan view.

Although the embodiments of the present disclosure have been described, it is understood that the present disclosure should not be limited to these embodiments but various changes and modifications can be made by one ordinary skilled in the art within the spirit and scope of the present disclosure as hereinafter claimed.

Therefore, the disclosed subject matter should not be limited to any single embodiment described herein, and the scope of the present invention shall be determined according to the attached claims.

What is claimed is:

1. A method of manufacturing a window including a folding area, a first non-folding area adjacent to one side of the folding area, and a second non-folding area adjacent to an opposite side of the folding area and comprising a substrate, a coating layer disposed under the substrate, and a black matrix, comprising:
placing the substrate in a guide film accommodating the substrate and provided with an opening, which is defined through the guide film to overlap a portion of the substrate in a plan view;
providing a first solution, which contains a light blocking particle and a polymer resin, to an edge portion of an inner space of the guide film, wherein the inner space is divided into a center portion overlapping the opening in the plan view and the edge portion, which is outside the center portion;
providing a second solution containing the polymer resin to the center portion;
placing a magnet to overlap the edge portion in the plan view to allow the light blocking particle to move by the magnet; and
curing the light blocking particle and the polymer resin using an ultraviolet light to form the black matrix and the coating layer.

2. The method of claim 1, wherein the coating layer comprises a first surface adjacent to the substrate and a second surface opposite to the first surface, and a portion of the first surface has a convex shape toward the substrate.

3. The method of claim 1, wherein the substrate comprises:
a first portion overlapping the first non-folding area;
a second portion overlapping the second non-folding area; and
a third portion overlapping the folding area and having a thickness smaller than each of thicknesses of the first and second portions, and the third portion has a curvature.

4. The method of claim 1, further comprising:
partially cutting the edge portion using a laser beam;
turning over the substrate and the coating layer; and
removing the guide film.

5. The method of claim 1, wherein the light blocking particle has ferromagnetism and a light blocking property.

6. The method of claim 3, wherein the light blocking particle is formed by coating a first material having a light blocking property on a first portion having ferromagnetism.

7. The method of claim 1, wherein the light blocking particle comprises Fe, Co, Ni, Mn, Fe₂O₃, or Fe₃O₄.

8. The method of claim 1, wherein the guide film comprises a transparent material, which transmits the ultraviolet light.

9. The method of claim 1, wherein placing the magnet to overlap the edge portion comprises:
placing the magnet under the guide film to allow the light blocking particle to be in contact with the substrate.

10. The method of claim 1, wherein placing the magnet to overlap the edge portion comprises:
placing the magnet on the guide film to allow the light blocking particle to be separated from the substrate and to be in contact with the guide film.

11. The method of claim 1, wherein placing the magnet to overlap the edge portion comprises:
placing the magnet on a side surface of the guide film to allow the light blocking particle to be arranged in a side surface of the substrate.

12. The method of claim 1, wherein curing the light blocking particle and the polymer resin comprises simultaneously forming the black matrix and the coating layer.

13. An electronic apparatus comprising:
a window comprising a folding area, a first non-folding area adjacent to one side of the folding area, and a second non-folding area adjacent to an opposite side of the folding area;
a display module disposed under the window; and
a housing accommodating the display module, the window comprising:
a substrate;
a coating layer disposed under the substrate; and
a black matrix, wherein the substrate has a concave shape in the folding area, the coating layer has a convex shape in the folding area, the substrate is spaced apart from the display module, the coating layer is disposed between the substrate and the display module, and the black matrix has ferromagnetism and a light blocking property.

14. The electronic apparatus of claim 13, further comprising:
an adhesive layer disposed under the window,
wherein the display module is disposed under the adhesive layer.

15. The electronic apparatus of claim 13, wherein the black matrix comprises a plurality of light blocking particles.

16. The electronic apparatus of claim 15, wherein each of the light blocking particles comprises:
a first portion having the ferromagnetism; and
a first material coated on the first portion and having the light blocking property.

17. The electronic apparatus of claim 15, wherein each of the light blocking particles comprises Fe, Co, Ni, Mn, Fe₂O₃, or Fe₃O₄.

18. The electronic apparatus of claim 13, wherein the black matrix is disposed between the substrate and the coating layer.

19. The electronic apparatus of claim 14, wherein the black matrix is disposed between the coating layer and the adhesive layer.

20. The electronic apparatus of claim 13, wherein the black matrix is disposed adjacent to a side surface of the substrate and a side surface of the coating layer, and the black matrix does not overlap the display module in a plan view.
